(19) United States
(12) Patent Application Publication
(10) Pub. No.: US 2025/0275299 A1
(43) Pub. Date: Aug. 28, 2025

(54) LIGHT-EMITTING DIODE EPITAXIAL STRUCTURE, AND METHOD FOR FORMING THE SAME

(71) Applicant: JADE BIRD DISPLAY (SHANGHAI) LIMITED, SHANGHAI (CN)

(72) Inventor: Weiwei SUN, Shanghai (CN)

(21) Appl. No.: 19/063,371

(22) Filed: Feb. 26, 2025

(30) Foreign Application Priority Data
Feb. 27, 2024 (CN) 202410218246.X

(51) Int. Cl. H10H 20/817; H10H 20/01; H10H 20/81; H10H 20/812; H10H 20/815; H10H 20/816; H10H 20/84

(52) U.S. Cl. CPC H10H 20/817; H10H 20/011; H10H 20/812; H10H 20/815; H10H 20/816; H10H 20/8215; H10H 20/84

(57) ABSTRACT

A light-emitting diode epitaxial structure and a method for forming the same are provided. The light-emitting diode epitaxial structure includes: an N-type semiconductor structure, a quantum well light-emitting layer and a P-type semiconductor structure which are stacked. The quantum well light-emitting layer is disposed between the N-type semiconductor structure and the P-type semiconductor structure. The P-type semiconductor structure includes a P-type current spreading layer and a P-type confinement layer, and the P-type confinement layer is disposed between the quantum well light-emitting layer and the P-type current spreading layer. A material of the P-type current spreading layer has a first lattice constant, a material of the P-type confinement layer has a second lattice constant, and a mismatch between the first lattice constant and the second lattice constant is less than or equal to 1%.

### CROSS-REFERENCE TO RELATED APPLICATIONS

This application claims the priority to Chinese Patent Application No. 202410218246.X, filed on Feb. 27, 2024, and entitled “LIGHT-EMITTING DIODE EPITAXIAL STRUCTURE, AND METHOD FOR FORMING THE SAME,” the content of which is incorporated herein by reference in its entirety.

### TECHNICAL FIELD

The present disclosure generally relates to the field of micro display technology, and more particularly, to a light-emitting diode epitaxial structure and a method for forming the light-emitting diode epitaxial structure.

### BACKGROUND

A micro LED refers to a high-density integrated light-emitting diodes array, and a pixel of a light-emitting diode is much smaller than a pixel of a conventional light-emitting diode. In the micro LED array, the distance between pixels is on the order of 10 microns, and currently, the pixel size of the high pixel density micro LED array is even less than 5 microns.

Due to the small size of the micro light-emitting diode, in order to reduce the proportion of the sidewall area, a thickness of a micro light-emitting diode epitaxial structure is also reduced accordingly and is generally less than 2 microns. Therefore, when the pixel size is reduced to 2.5 microns or even 1 micron, a highly flat epitaxial wafer surface of the epitaxial structure is needed to ensure a contact yield between the surface of the epitaxial structure and a conductive structure.

However, it is difficult to ensure that the light-emitting diode epitaxial structure formed via existing processes has a highly flat surface, which leads to a reduction of the contact yield between the surface of the light-emitting diode epitaxial structure and the conductive structure.

### SUMMARY

Embodiments of the present disclosure provide a light-emitting diode epitaxial structure and a method for forming the light-emitting diode epitaxial structure to improve a contact yield between a surface of the light-emitting diode epitaxial structure and a conductive structure.

For solving above problems, embodiments of the present disclosure provide a light-emitting diode epitaxial structure. The light-emitting diode epitaxial structure includes: an N-type semiconductor structure; a quantum well light-emitting layer disposed on the N-type semiconductor structure; and a P-type semiconductor structure disposed on the quantum well light-emitting layer. The P-type semiconductor structure includes a P-type current spreading layer and a P-type confinement layer, the P-type confinement layer is disposed between the quantum well light-emitting layer and the P-type current spreading layer, and the P-type confinement layer and the P-type current spreading layer are in close contact and matched in lattice.

Accordingly, embodiments of the present disclosure also provide a method for forming a light-emitting diode epitaxial structure. The method includes: providing a substrate; forming an N-type semiconductor structure on the substrate; forming a quantum well light-emitting layer on the N-type semiconductor structure; forming a P-type confinement layer on the quantum well light-emitting layer; and forming a P-type current spreading layer on the P-type confinement layer, and the P-type confinement layer and the P-type current spreading layer being in close contact and matched in lattice.

Accordingly, embodiments of the present disclosure also provide a method for forming a light-emitting diode epitaxial structure. The method includes: providing a substrate; forming a P-type current spreading layer on the substrate; forming a P-type confinement layer on the P-type current spreading layer, and the P-type confinement layer and the P-type current spreading layer being in close contact and matched in lattice; forming a quantum well light-emitting layer on the P-type confinement layer; and forming an N-type semiconductor structure on the quantum well light-emitting layer.

Compared with conventional technology, embodiments of the present disclosure may have following advantages.

According to the light-emitting diode epitaxial structure of embodiments of the present disclosure, by matching the lattice constant of the P-type current spreading layer with the lattice constant of the P-type confinement layer, the P-type current spreading layer with a flat surface can be formed directly on the P-type confinement layer, or the P-type confinement layer with a flat surface can be formed directly on the P-type current spreading layer. Therefore, a top of the diode structure has a flat surface, which is conducive to improving an electrical contact yield between the top of the diode structure and a conductive structure, thereby enhancing the performance of the light-emitting diode.

Further, the material of the P-type current spreading layer is AlᵢGa₁₋ᵢAs, and 0.7≤i<1. On one hand, the AlᵢGa₁₋ᵢAs may be doped with a high doping concentration of P-type particles such as Mg, C or Zn, ensuring that the P-type current spreading layer has a high conductivity and can achieve an ohmic contact with other structures. On the other hand, the composition of Al in the AlᵢGa₁₋ᵢAs can be flexibly adjusted, especially when i≥0.7, a full transmission of red light can be realized, a light transmittance of the diode structure can thus be enhanced, and a brightness of the light-emitting diode device can be improved.

### BRIEF DESCRIPTION OF THE DRAWINGS

FIG. 1 schematically illustrates a cross-sectional view of a light-emitting diode epitaxial structure according to an embodiment;

FIG. 2 schematically illustrates a flow chart of a process of forming a light-emitting diode epitaxial structure according to an embodiment of the present disclosure;

FIG. 3 schematically illustrates cross-sectional views corresponding to the process of forming the light-emitting diode epitaxial structure shown in FIG. 2;

FIG. 4 schematically illustrates a cross-sectional view of a light-emitting diode epitaxial structure according to an embodiment of the present disclosure;

FIG. 5 schematically illustrates a flow chart of a process of forming a light-emitting diode epitaxial structure according to another embodiment of the present disclosure;

FIG. 6 schematically illustrates cross-sectional views corresponding to the process of forming the light-emitting diode epitaxial structure shown in FIG. 5; and

FIG. 7 schematically illustrates a cross-sectional view of a light-emitting diode epitaxial structure according to another embodiment of the present disclosure.

### DETAILED DESCRIPTION

As mentioned in the background, it is difficult to ensure that a light-emitting diode formed by existing processes has a flat surface, which leads to a reduction of a yield of the light-emitting diode.

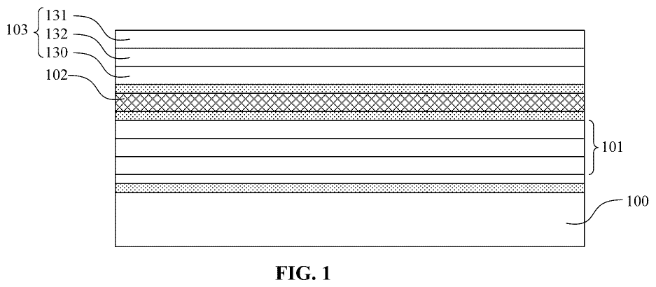

FIG. 1 schematically illustrates a cross-sectional view of a light-emitting diode epitaxial structure according to an embodiment. The light-emitting diode epitaxial structure includes: a substrate 100; an N-type semiconductor structure 101 disposed on the substrate 100, a quantum well light-emitting layer 102 disposed on the N-type semiconductor structure 101, and a P-type semiconductor structure 103 disposed on the quantum well light-emitting layer 102. The P-type semiconductor structure 103 includes a P-type confinement layer 130 disposed on the quantum well light-emitting layer 102 and a P-type current spreading layer 131 disposed on the P-type confinement layer 130. A material of the P-type confinement layer 130 is AlInP, and a material of the P-type current spreading layer 131 is GaP.

When the material of the P-type current spreading layer 131 is GaP, the P-type current spreading layer 131 has advantages such as extremely high light transmittance and electrical conductivity. However, since a lattice constant of the GaP material of the P-type current spreading layer 131 is 5.45 Å and a lattice constant of the AlInP material of the P-type confinement layer 130 is 5.65 Å, a lattice mismatch between the GaP and the AlInP reaches 3.6%. Therefore, the P-type current spreading layer 131 formed on the P-type confinement layer 130 through an existing epitaxial process is prone to have an island-like structure, leading to an uneven surface, which results in a poor electrical contact performance between the light-emitting diode epitaxial structure and an external conductive structure.

One method for solving the above problem is to form a P-type transition layer 132 between the P-type confinement layer 130 and the P-type current spreading layer 131, and a material of the P-type transition layer 132 is AlGaInP. However, it is still difficult to eliminate the lattice mismatch between the P-type confinement layer 130 and the P-type current spreading layer 131, and can also lead to an increase in a thickness of the light-emitting diode epitaxial structure, which is not conducive to the miniaturization of the light-emitting diode device.

According to embodiments of the present disclosure, a light-emitting diode epitaxial structure and a method for forming the light-emitting diode epitaxial structure are provided, which can improve a flatness of a top surface of the light-emitting diode epitaxial structure, improve an electrical contact yield between the top of the light-emitting diode epitaxial structure and a conductive structure, and thus improve a performance of the light-emitting diode device.

Embodiments of the present disclosure provide a method for forming a light-emitting diode epitaxial structure.

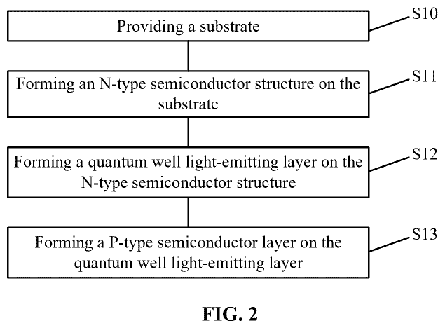

FIG. 2 schematically illustrates a flow chart of a process of forming a light-emitting diode epitaxial structure according to an embodiment of the present disclosure. According to some embodiments of the present disclosure, the method for in forming the light-emitting diode epitaxial structure includes:

Step S10, providing a substrate;

Step S11, forming an N-type semiconductor structure on the substrate;

Step S12, forming a quantum well light-emitting layer on the N-type semiconductor structure; and

Step S13, forming a P-type semiconductor layer on the quantum well light-emitting layer.

In order to clarify the object, features and advantages of the present disclosure, the embodiments of the present disclosure will be described clearly in detail in conjunction with accompanying figures.

It should be noted that the terms “on” and the like used in the embodiments of the present disclosure are only used to indicate a relative positional relationship, and are not used to restrict a specific positional relationship such as direct contact between the two. Therefore, these terms should not be construed as limitations on the present disclosure.

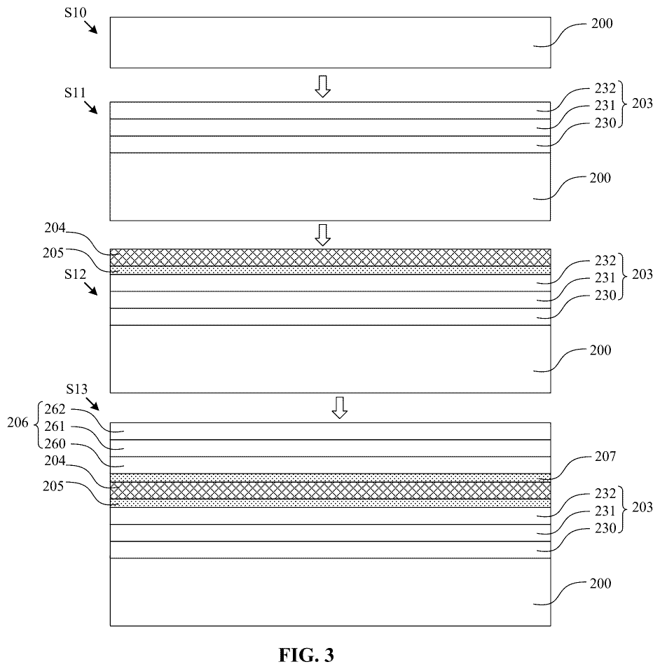

FIG. 3 schematically illustrates cross-sectional views corresponding to the process of forming the light-emitting diode epitaxial structure shown in FIG. 2.

Referring to FIG. 2 and FIG. 3, the step S10 is performed to provide a substrate 200.

In some embodiments, a material of the substrate 200 is GaAs, and the GaAs material facilitates the subsequent formation of a light-emitting diode epitaxial structure on the substrate 200 through an epitaxial process.

In some embodiments, the substrate 200 is doped with N-type particles, the N-type particles include at least one selected from a group consisting of Si and Te, a doping concentration of the N-type particles ranges from 0.4×10¹⁸ atoms/cm³ to 4×10¹⁸ atoms/cm³, and the N-type particles include N-type atoms or N-type ions.

In some embodiments, the substrate 200 is doped with P-type particles, the P-type particles include at least one selected from a group consisting of Mg, C and Zn, a doping concentration of the P-type particles ranges from 0.4×10¹⁸ atoms/cm³ to 4×10¹⁸ atoms/cm³, and the P-type particles include P-type atoms or P-type ions.

Referring to FIG. 2 and FIG. 3, the step S11 is performed to form an N-type semiconductor structure 203 on the substrate 200.

A method for forming the N-type semiconductor structure 203 includes: forming an N-type ohmic contact layer 230 on the substrate 200; forming an N-type current spreading layer 231 on the N-type ohmic contact layer 230; and forming an N-type confinement layer 232 on the N-type current spreading layer 231.

The N-type ohmic contact layer 230 serves as an N-type electrode, the N-type current spreading layer 231 is used for current spreading in the N-side of the light-emitting diode, and the N-type confinement layer 232 is used to provide electrons to the quantum well light-emitting layer 204.

A material of the N-type ohmic contact layer 230 may be GaAs. The N-type ohmic contact layer 230 may be formed through an epitaxial deposition process. The N-type ohmic contact layer 230 may be doped with N-type particles, and the N-type particles include at least one selected from a group consisting of Si and Te. In some embodiments, the N-type particles include Si particles, and a doping concentration of the Si particles is more than 5.0×10¹⁸ atoms/cm³. The N-type particles may be doped into the N-type ohmic contact layer 230 via a vapor-phase epitaxy process or a molecular beam epitaxy process. The N-type ohmic contact layer 230 with a relatively high doping concentration of the N-type particles can readily form an ohmic contact with other electrically connected structures.

A material of the N-type current spreading layer 231 may be (Al_{y}Ga_{1-y})_{0.5}In_{0.5}P, and 0<y<1. The N-type current spreading layer 231 may be formed through an epitaxial deposition process. The N-type current spreading layer 231 may be doped with N-type particles, and the N-type particles may include at least one selected from a group consisting of Si and Te. In some embodiment, the N-type particles include Si particles, and a doping concentration of the Si particles is more than 1.0×10¹⁸ atoms/cm³ to 2.0×10¹⁸ atoms/cm³. The N-type particles may be doped into the N-type current spreading layer 231 via a vapor-phase epitaxy process or a molecular beam epitaxy process.

A material of the N-type confinement layer 232 may be Al_{0.5}In_{0.5}P. The N-type confinement layer 232 may be formed through an epitaxial deposition process. The N-type confinement layer 232 may be doped with N-type particles, and the N-type particles include at least one selected from a group consisting of Si and Te. In some embodiment, the N-type particles include Si particles, and a doping concentration of the Si particles is more than 1.0×10¹⁸ atoms/cm³ to 2.0×10¹⁸ atoms/cm³. The N-type particles may be doped into the N-type confinement layer 232 via a vapor-phase epitaxy process or a molecular beam epitaxy process.

The N-type particles include N-type atoms or N-type ions.

Referring to FIG. 2 and FIG. 3, the step S12 is performed to form a quantum well light-emitting layer 204 on the N-type semiconductor structure 203.

The quantum well light-emitting layer 204 may be formed through an epitaxial deposition process. In the quantum well light-emitting layer 204, light generated by the recombination of electrons and holes radiates outwardly. A material of the quantum well light-emitting layer 204 may be Al_{w}Ga_{z}In_{1-w-z}P, 0<w<1, 0<z<1, and (w+z)<1. A lattice constant of the Al_{w}Ga_{z}In_{1-w-z}P may be 5.65 Å. In some embodiments, the quantum well light-emitting layer 204 may not be doped with P-type particles or N-type particles.

In some embodiments, the method for forming the light-emitting diode epitaxial structure further includes step S14: forming a first waveguide layer 205 on the N-type semiconductor structure 203 before forming the quantum well light-emitting layer 204. The first waveguide layer 205 is used to protect light-emitting regions.

The first waveguide layer 205 may be formed through an epitaxial deposition process. A material of the first waveguide layer 205 may be (AlᵥGa₁₋ᵥ)_{0.5}In_{0.5}P, and 0.6≤v<1. A lattice constant of the (AlᵥGa₁₋ᵥ)_{0.5}In_{0.5}P may be 5.65 Å. The composition v of Al in the (AlᵥGa₁₋ᵥ)_{0.5}In_{0.5}P is not less than 0.6, which provides the first waveguide layer 205 with a light transmittance and is conducive to reducing optical loss in the quantum well light-emitting layer 204. In some embodiments, the first waveguide layer 205 is not doped with N-type particles or P-type particles.

The lattice of the first waveguide layer 205 matches the lattice of the quantum well light-emitting layer 204, ensuring a performance and a service life of the device including the light-emitting diode epitaxial structure of the present disclosure, and facilitating a crystal growth of the quantum well light-emitting layer 204. Additionally, the first waveguide layer 205 prevents doping particles or other impurity particles in the N-type semiconductor structure 203 from entering the quantum well light-emitting layer 204, ensuring a light-emitting efficiency of the quantum well light-emitting layer 204.

Referring to FIG. 2 and FIG. 3, the step S13 is performed to form a P-type semiconductor layer 206 on the quantum well light-emitting layer 204.

In some embodiments, the method for forming the light-emitting diode epitaxial structure further includes step S15: forming a second waveguide layer 207 on the quantum well light-emitting layer 204 before forming the P-type semiconductor structure 206. The second waveguide layer 207 is used to protect the light-emitting regions.

The second waveguide layer 207 may be formed through an epitaxial deposition process. A material of the second waveguide layer 207 may be (AlᵤGa₁₋ᵤ)_{0.5}In_{0.5}P, and 0.6≤u<1. A lattice constant of the (AlᵤGa₁₋ᵤ)_{0.5}In_{0.5}P may be 5.65 Å. The composition u of Al in the (AlᵤGa₁₋ᵤ)_{0.5}In_{0.5}P is not less than 0.6, which provides the second waveguide layer 207 with a high light transmittance and is conducive to reducing optical loss in the quantum well light-emitting layer 204. In some embodiments, the second waveguide layer 207 is not doped with N-type particles or P-type particles.

The lattice of the second waveguide layer 207 matches the lattice of the quantum well light-emitting layer 204, ensuring a performance and a service life of the device including the light-emitting diode epitaxial structure of the present disclosure, and facilitating a crystal growth of the P-type semiconductor structure 206. Additionally, the second waveguide layer 207 prevents doping particles or other impurity particles in the P-type semiconductor structure 206 from entering the quantum well light-emitting layer 204, ensuring a light-emitting efficiency of the quantum well light-emitting layer 204.

In other embodiments, any one of the first waveguide layer and the second waveguide layer can be formed.

A method for forming the P-type semiconductor structure 206 includes: forming a P-type confinement layer 260 on the second waveguide layer 207; and forming a P-type current spreading layer 261 on the P-type confinement layer 260.

The P-type confinement layer 260 is used to provide holes to the quantum well light-emitting layer 204; and the P-type current spreading layer 261 is used for current spreading in a P-side of the light-emitting diode.

A material of the P-type current spreading layer 261 has a first lattice constant, a material of the P-type confinement layer 260 has a second lattice constant, and a mismatch between the first lattice constant and second lattice constant is less than or equal to 1%.

On one hand, the lattice constants of the P-type current spreading layer 261 and the P-type confinement layer 260 are close to each other, the P-type current spreading layer 261 formed on the P-type confinement layer 260 through the epitaxial deposition process has a well-aligned lattice arrangement, and dislocations and lattice mismatches between the P-type current spreading layer 261 and P-type confinement layer 260 are thus not prone to occur. Therefore, the P-type current spreading layer 261 formed through the epitaxial deposition process has a flat surface, which is conducive to improving the contact yield between the surface of the P-type semiconductor structure 206 and the conductive structure.

On the other hand, the lattice constants of the P-type current spreading layer 261 and the P-type confinement layer 260 are close to each other, the P-type current spreading layer 261 can be formed directly on the P-type confinement layer 260 without forming a transition material layer between the P-type current spreading layer 261 and the P-type confinement layer 260, which is conducive to further reducing a structural size of the light-emitting diode.

In some embodiments, the material of the P-type confinement layer 260 is Al_{0.5}In_{0.5}P, and a lattice constant of the Al_{0.5}In_{0.5}P is 5.65 Å. The P-type confinement layer 260 is doped with P-type particles, and the P-type particles include at least one selected from a group consisting of Mg, C, and Zn. In some embodiments, the P-type particles include Mg particles. A doping concentration of the P-type particles in the P-type confinement layer 260 ranges from 0.4×10¹⁸ atoms/cm³ to 1×10¹⁸ atoms/cm³. The P-type confinement layer 260 may be formed through an epitaxial deposition process. The P-type particles may be doped into the P-type confinement layer 260 via a vapor-phase epitaxy process or a molecular beam epitaxy process.

In some embodiments, the material of the P-type current spreading layer 261 is AlᵢGa₁₋ᵢAs, and 0.7≤i<1. A lattice constant of the AlᵢGa₁₋ᵢAs is 5.65 Å. The P-type current spreading layer 261 is doped with P-type particles, and the P-type particles include at least one selected from a group consisting of Mg, C, and Zn. A doping concentration of the P-type particles in the P-type current spreading layer 261 is greater than 3.0×10¹⁸ atoms/cm³. The P-type particles may be doped into the P-type current spreading layer 261 via a vapor-phase epitaxy process or a molecular beam epitaxy process.

In some embodiments, the P-type particles in the P-type current spreading layer 261 include C particles, and the C particles can be easily doped into the P-type current spreading layer 261, which ensures that the P-type current spreading layer 261 doped with the C particles has a high electrical conductivity and a high light transmittance, thereby reducing optical loss.

On one hand, the material of the P-type current spreading layer 261 is AlᵢGa₁₋ᵢAs, and 0.7≤i<1. The AlᵢGa₁₋ᵢAs can be doped with a high doping concentration of the P-type particles including at least one selected from a group consisting of Mg, C, and Zn, which ensures that the P-type current spreading layer 261 has a high electrical conductivity and can achieve an ohmic contact with the conductive structure.

On the other hand, the material of the P-type current spreading layer 261 is AlᵢGa₁₋ᵢAs, and 0.7≤i<1. Since the composition of Al in the AlᵢGa₁₋ᵢAs can be flexibly adjusted, optical properties and electrical properties of the P-type current spreading layer 261 can be flexibly adjusted. In particular, when i≥0.7, a full transmission of red light can be realized. The AlᵢGa₁₋ᵢAs is particularly suitable for use as a surface window material for a light-emitting diode to improve a light transmittance of the light-emitting diode and improve a brightness of the light-emitting diode device.

In some embodiments, the P-type current spreading layer 261 may be formed through an epitaxial deposition process, and the P-type particles may be doped into the P-type current spreading layer 261 via a vapor-phase epitaxy process or a molecular beam epitaxy process. In some embodiments, parameters of the epitaxial deposition process for forming the P-type current spreading layer 261 includes: a pressure ranging from 40 mbar to 60 mbar, a temperature ranging from 700° C. to 750° C., and reaction gases include an arsenic source gas, a gallium source gas, an aluminum source gas, and a P-type doping source gas.

In some embodiments, after the arsenic source gas is introduced into a process chamber used for the epitaxial deposition process, the gallium source gas, the aluminum source gas, and the P-type doping source gas are introduced. Therefore, the composition of Al, the composition of Ga, and the doping concentration of the P-type particles in the material can be flexibly controlled by adjusting the flow rate of the gas sources. In an embodiment, the arsenic source gas includes AsH₃; the gallium source gas includes trimethyl gallium; and the aluminum source gas includes trimethyl aluminum.

In some embodiments, the material of the P-type current spreading layer is AlGaInP.

In some embodiments, the method for forming the P-type semiconductor structure 206 further includes: forming a P-type ohmic contact layer 262 on the P-type current spreading layer 261. The P-type ohmic contact layer 262 and the P-type confinement layer 260 are respectively disposed on opposite sides of the P-type current spreading layer 261. In other embodiments, the P-type ohmic contact layer 262 is not needed.

In some embodiments, the P-type ohmic contact layer 262 serves as a P-type electrode. Moreover, the P-type ohmic contact layer 262 can protect the P-type current spreading layer 261 from oxidization, especially the oxidation of Al in the P-type current spreading layer 261, ensuring the performance of the P-type current spreading layer 261.

A material of the P-type ohmic contact layer 262 may be GaAs, the P-type ohmic contact layer 262 may be doped with P-type particles, and a doping concentration of the P-type particles may be greater than 1.0×10¹⁹ atoms/cm³. The P-type particles may include at least one selected from a group consisting of Mg, C, and Zn. In some embodiments, the P-type particles include C particles, and the C particles can be easily doped into the P-type ohmic contact layer 262, which ensures that the P-type ohmic contact layer 262 doped with the C particles has a high electrical conductivity. The P-type ohmic contact layer 262 may be formed through an epitaxial deposition process, and the P-type particles may be doped into the P-type ohmic contact layer 262 via a vapor-phase epitaxy process or a molecular beam epitaxy process.

The P-type particles include P-type ions or P-type atoms.

In some embodiments, parameters of the epitaxial deposition process for forming the P-type ohmic contact layer 262 include: a pressure ranging from 40 mbar to 60 mbar, a temperature ranging from 700° C. to 750° C., and reaction gases including an arsenic source gas, a gallium source gas, and a P-type doping source gas.

In some embodiments, on the basis of the process for forming the P-type current spreading layer 261, the arsenic source gas atmosphere in the process chamber used for the epitaxial deposition process may be kept unchanged, the aluminum source gas is not introduced, and the gallium source gas and the P-type doping source gas are introduced. In an embodiment, the arsenic source gas includes AsH₃, and the gallium source gas includes trimethyl gallium.

In some embodiments, a method for forming a light-emitting diode includes: after forming the P-type semiconductor structure 206, removing the substrate 200 until a surface of the N-type ohmic contact layer 230 is exposed. A process for removing the substrate 200 may include: a dry etching process, a wet etching process, and a chemical mechanical polishing process.

By matching the lattice constant of the P-type current spreading layer 262 with lattice constants of the P-type confinement layer 261, the quantum well light-emitting layer 204, and the second waveguide layer 207, the P-type current spreading layer having a flat surface can be formed on the quantum well light-emitting layer 204 through the epitaxial deposition process. Therefore, the top of the light-emitting diode epitaxial structure has a flat surface, which is conducive to improving the electrical contact yield between the top of the light-emitting diode epitaxial structure and the conductive structure, and improving the performance of the light-emitting diode.

Embodiments of the present disclosure also provide a light-emitting diode epitaxial structure which can be formed through aforementioned method. Referring to FIG. 3, the light-emitting diode epitaxial structure formed through the aforementioned method includes: a substrate 200; an N-type semiconductor structure 203 disposed on the substrate 200; a quantum well light-emitting layer 204 disposed on the N-type semiconductor structure 203; and a P-type semiconductor structure 206 disposed on the quantum well light-emitting layer 204. The P-type semiconductor structure 206 includes a P-type current spreading layer 260 and a P-type confinement layer 261, and the P-type confinement layer 261 and the P-type current spreading layer 260 are in close contact and matched in lattice.

Following provides a detailed description in conjunction with the accompanying drawings.

In some embodiments, a material of the P-type current spreading layer 261 has a first lattice constant, a material of the P-type confinement layer 260 has a second lattice constant, and a mismatch between the first lattice constant and the second lattice constant is less than or equal to 1%.

The P-type confinement layer 260 is used to provide holes to the quantum well light-emitting layer 204. In some embodiments, a material of the P-type confinement layer 260 is Al_{0.5}In_{0.5}P, and a lattice constant of the Al_{0.5}In_{0.5}P is 5.65 Å. The P-type confinement layer 260 is doped with P-type particles, and the P-type particles include at least one selected from a group consisting of Mg, C, and Zn. In some embodiments, the P-type particles include Mg particles. A doping concentration of the P-type particles in the P-type confinement layer 260 ranges from 0.4×10¹⁸ atoms/cm³ to 1×10¹⁸ atoms/cm³.

A material of the P-type current spreading layer 261 may be AlᵢGa₁₋ᵢAs, and 0.7≤i<1. A lattice constant of the AlᵢGa₁₋ᵢAs may be 5.65 Å. The P-type current spreading layer 261 may be doped with P-type particles, and the P-type particles may include at least one selected from a group consisting of Mg, C, and Zn. In some embodiments, the P-type particles include C particles. A doping concentration of the P-type particles in the P-type current spreading layer 261 may be greater than 3.0×10¹⁸ atoms/cm³.

In some embodiments, the material of the P-type current spreading layer 261 is AlGaInP.

The P-type semiconductor structure 206 also includes a P-type ohmic contact layer 262, and the P-type ohmic contact layer 262 and the P-type confinement layer 260 are disposed on opposite side of the P-type current spreading layer 261. In some embodiments, the P-type ohmic contact layer 262 is disposed on a top of the P-type current spreading layer 261. In other embodiments, the P-type ohmic contact layer 262 may not be needed.

The P-type ohmic contact layer 262 can serve as a P-type electrode. Moreover, the P-type ohmic contact layer 262 can protect the P-type current spreading layer 261 from oxidization, especially the oxidation of Al in the P-type current spreading layer 261, ensuring the performance of the P-type current spreading layer 261.

A material of the P-type ohmic contact layer 262 may be GaAs, the P-type ohmic contact layer 262 may be doped with P-type particles, and a doping concentration of the P-type particles may be greater than 1.0×10¹⁹ atoms/cm³. The P-type particles may include at least one selected from a group consisting of Mg, C, and Zn. In some embodiments, the P-type particles include C particles.

The N-type semiconductor structure 203 includes an N-type confinement layer 232, an N-type current spreading layer 231, and an N-type ohmic contact layer 230. The N-type confinement layer 232 is disposed between the quantum well light-emitting layer 204 and the N-type current spreading layer 231, and the N-type current spreading layer 231 is disposed between the N-type confinement layer 232 and the N-type ohmic contact layer 230.

The N-type ohmic contact layer 230 serves as an N-type electrode, the N-type current spreading layer 231 is used for current spreading in the N-side of the light-emitting diode, and the N-type confinement layer 232 is used to provide electrons to the quantum well light-emitting layer 204.

A material of the N-type ohmic contact layer 230 may be GaAs. The N-type ohmic contact layer 230 may be doped with N-type particles, and the N-type particles may include at least one selected from a group consisting of Si and Te. In some embodiments, the N-type particles include Si particles, and a doping concentration of the Si particles is more than 5.0×10¹⁸ atoms/cm³. The N-type ohmic contact layer 230 with a relatively high doping concentration of the N-type particles can readily form an ohmic contact with a conductive structure.

A material of the N-type current spreading layer 231 may be (Al_{y}Ga_{1-y})_{0.5}In_{0.5}P, and 0<y<1. The N-type current spreading layer 231 may be doped with N-type particles, and the N-type particles may include at least one selected from a group consisting of Si and Te. In some embodiment, the N-type particles include Si particles, and a doping concentration of the Si particles is more than 1.0×10¹⁸ atoms/cm³ to 2.0×10¹⁸ atoms/cm³.

A material of the N-type confinement layer 232 may be Al_{0.5}In_{0.5}P. The N-type confinement layer 232 may be doped with N-type particles, and the N-type particles may include at least one selected from a group consisting of Si and Te. In some embodiment, the N-type particles include Si particles, and a doping concentration of the Si particles is more than 1.0×10¹⁸ atoms/cm³ to 2.0×10¹⁸ atoms/cm³.

In some embodiments, the light-emitting diode epitaxial structure further includes: a first waveguide layer 205 disposed between the quantum well light-emitting layer 204 and the N-type semiconductor structure 203; and a second waveguide layer 207 disposed between the quantum well light-emitting layer 204 and the P-type confinement layer 260. The first waveguide layer 205 and the second waveguide layer 207 are used to protect the light-emitting regions.

A material of the first waveguide layer 205 may be (AlᵥGa₁₋ᵥ)_{0.5}In_{0.5}P, and 0.6≤v<1. The composition v of Al in the (AlᵥGa₁₋ᵥ)_{0.5}In_{0.5}P is not less than 0.6, which provides the first waveguide layer 205 with a high light transmittance and is conducive to reducing optical loss in the quantum well light-emitting layer 204. In some embodiments, the first waveguide layer 205 is not doped with N-type particles or P-type particles.

A material of the second waveguide layer 207 may be (AlᵤGa₁₋ᵤ)_{0.5}In_{0.5}P, and 0.6≤u<1. A lattice constant of the (AlᵤGa₁₋ᵤ)_{0.5}In_{0.5}P may be 5.65 Å. The composition u of Al in the (AlᵤGa₁₋ᵤ)_{0.5}In_{0.5}P is not less than 0.6, which provides the second waveguide layer 207 with a high light transmittance and is conducive to reducing optical loss in the quantum well light-emitting layer 204. In some embodiments, the second waveguide layer 207 is not doped with N-type particles or P-type particles.

In other embodiments, the light-emitting diode epitaxial structure may include only one of the first waveguide layer and the second waveguide layer.

In some embodiments, a material of the substrate 200 is GaAs, the substrate 200 is doped with N-type particles, the N-type particles include at least one selected from a group consisting of Si and Te, and a doping concentration of the N-type particles ranges from 0.4×10¹⁸ atoms/cm³ to 4.0×10¹⁸ atoms/cm³.

In some embodiments, the substrate is doped with P-type particles, the P-type particles include at least one selected from a group consisting of Mg, C and Zn, and a doping concentration of the P-type particles ranges from 0.4×10¹⁸ atoms/cm³ to 4×10¹⁸ atoms/cm³.

In some embodiments, the N-type particles include N-type atoms or N-type ions, and the P-type particles include P-type atoms or P-type ions.

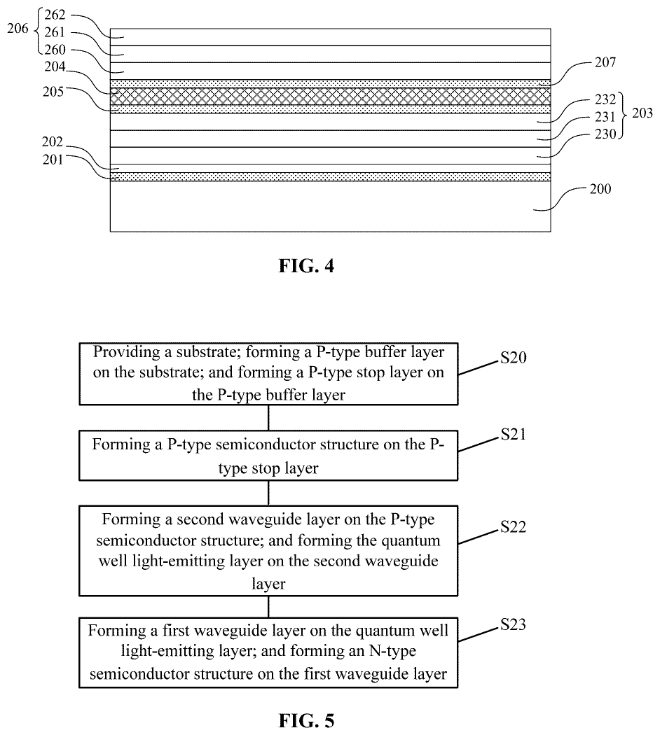

FIG. 4 schematically illustrates a cross-sectional view of a light-emitting diode epitaxial structure according to an embodiment of the present disclosure.

Unlike the embodiments illustrated in FIG. 2 and FIG. 3, in this embodiment, the method for forming the light-emitting diode epitaxial structure includes: before forming the N-type semiconductor structure, sequentially forming an N-type buffer layer 201 and an N-type stop layer 202 on a surface of the substrate 200. The method of forming the light-emitting diode epitaxial structure further includes: forming the N-type semiconductor structure 203 on the N-type stop layer 202; forming the quantum well light-emitting layer 204 on the N-type semiconductor structure 203; and forming the P-type semiconductor structure 206 on the quantum well light-emitting layer 204.

The process of forming the light-emitting diode epitaxial structure is illustrated in FIG. 2 and FIG. 3 and related description, and is not be repeated herein.

In some embodiments, before forming the N-type semiconductor structure 203, an N-type buffer layer 201 is formed on the substrate 200 and an N-type stop layer 202 is formed on the N-type buffer layer 201.

The N-type buffer layer 201 is used to reduce impurities on the surface of the substrate 200 and mitigate the impact of dislocations on the N-type semiconductor structure 203, the P-type semiconductor structure 206, and the quantum well light-emitting layer 204, thereby facilitating the formation of the light-emitting diode epitaxial structure having a relatively flat surface.

The N-type stop layer 202 is used to protect the N-type ohmic contact layer 230 from damage during subsequent removal of the substrate 200, ensuring that the N-type ohmic contact layer 230 has a good ohmic contact effect.

In some embodiments, the N-type semiconductor structure is formed on the N-type stop layer 202. Therefore, the N-type buffer layer 201 and the N-type stop layer 202 are doped with N-type particles. The N-type particles include at least one selected from a group consisting of Si and Te; and the N-type particles include N-type atoms or N-type ions.

A material of the N-type buffer layer 201 may be GaAs, and the N-type buffer layer 201 may be formed through an epitaxial deposition process. In some embodiments, Si is doped into the N-type buffer layer 201, and a doping concentration of Si ranges from 1.0×10¹⁸ atoms/cm³ to 2.0×10¹⁸ atoms/cm³. The N-type particles may be doped into the N-type buffer layer 201 via a vapor-phase epitaxy process or a molecular beam epitaxy process.

A material of the N-type stop layer 202 may be (AlₓGa₁₋ₓ)_{0.5}In_{0.5}P, and 0≤x<1. The N-type stop layer 202 may be formed through an epitaxial deposition process. In some embodiments, Si is doped into the N-type stop layer 202, and a doping concentration of Si ranges from 1.0×10¹⁸ atoms/cm³ to 2.0×10¹⁸ atoms/cm³. The N-type particles may be doped into the N-type stop layer 202 via a vapor-phase epitaxy process or a molecular beam epitaxy process.

The N-type particles include N-type atoms or N-type ions.

In some embodiments, the N-type semiconductor structure 203, the quantum well light-emitting layer 204, and the P-type semiconductor structure 206 are formed and stacked on the N-type stop layer 202. The quantum well light-emitting layer 204 is disposed between the N-type semiconductor structure 203 and the P-type semiconductor structure 206. The P-type semiconductor structure 206 includes a P-type current spreading layer 261 and a P-type confinement layer 260, and the P-type confinement layer 260 is disposed between the quantum well light-emitting layer 204 and the P-type current spreading layer 261.

In some embodiments, the method for forming the light-emitting diode includes: after forming the P-type semiconductor structure 206, removing the substrate 200 until a surface of the N-type ohmic contact layer 230 is exposed. The N-type stop layer 202 is used to protect the N-type ohmic contact layer 230 from damage during the removal of the substrate 200, ensuring that the N-type ohmic contact layer 230 has good ohmic contact properties.

Another embodiments of the present disclosure provide a method for forming a light-emitting diode epitaxial structure.

FIG. 5 schematically illustrates a flow chart of a process of forming a light-emitting diode epitaxial structure according to another embodiment of the present disclosure. The method for forming the light-emitting diode epitaxial structure provided by another embodiment of the present disclosure includes:

Step S20, providing a substrate; forming a P-type buffer layer on the substrate; and forming a P-type stop layer on the P-type buffer layer;

Step S21, forming a P-type semiconductor structure on the P-type stop layer;

Step S22, forming a second waveguide layer on the P-type semiconductor structure; and forming the quantum well light-emitting layer on the second waveguide layer; and

Step S23, forming a first waveguide layer on the quantum well light-emitting layer; and forming an N-type semiconductor structure on the first waveguide layer.

Specific embodiments of the present disclosure are described in detail below in conjunction with the accompanying drawings.

Unlike the embodiments illustrated in FIG. 2 and FIG. 3, in this embodiment, the method for forming the light-emitting diode epitaxial structure includes: forming the P-type semiconductor structure on the P-type stop layer; forming the quantum well light-emitting layer on the P-type semiconductor structure; and forming the N-type semiconductor structure on the quantum well light-emitting layer.

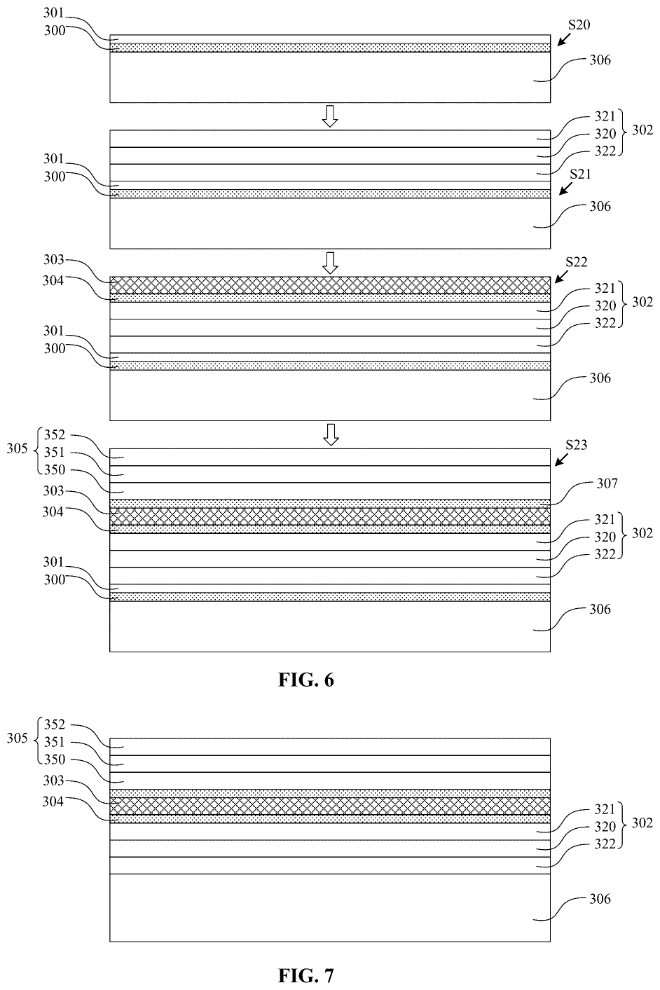

Referring to FIG. 5 and FIG. 6, the step S20 is performed to provide a substrate 306, to form a P-type buffer layer 300 on the substrate 306, and to form a P-type stop layer 301 on the P-type buffer layer 300.

In some embodiments, a material of the substrate 306 is GaAs, and the GaAs material facilitates the subsequent formation of a light-emitting diode epitaxial structure on the substrate 306 through an epitaxial process.

In some embodiments, the substrate 306 is doped with P-type particles, the P-type particles include at least one selected from a group consisting of Mg, C and Zn, a doping concentration of the P-type particles ranges from 0.4×10¹⁸ atoms/cm³ to 4×10¹⁸ atoms/cm³, and the P-type particles include P-type atoms or P-type ions.

In some embodiments, the substrate 306 is doped with N-type particles, the N-type particles include at least one selected from a group consisting of Si and Te, a doping concentration of the N-type particles ranges from 0.4×10¹⁸ atoms/cm³ to 4×10¹⁸ atoms/cm³, and the N-type particles include N-type atoms or N-type ions.

In some embodiments, the P-type buffer layer 300 is used to reduce impurities on the surface of the substrate 306 and mitigate the impact of dislocations on the P-type semiconductor structure 302, the N-type semiconductor structure 305, and the quantum well light-emitting layer 303, facilitating the formation the light-emitting diode epitaxial structure having a relatively flat surface.

The P-type stop layer 301 is used to protect the P-type ohmic contact layer 322 from damage during subsequent removal of the substrate 306, ensuring that the subsequent formed P-type ohmic contact layer 230 has a good ohmic contact effect.

In some embodiments, the P-type semiconductor structure 302 is subsequently formed on the substrate 306. The P-type buffer layer 300 and the P-type stop layer 301 may be doped with P-type particles, and the P-type particles may include at least one selected from a group consisting of Mg, C, and Zn.

A material of the P-type buffer layer 300 may be GaAs, and the P-type buffer layer 300 may be formed through an epitaxial deposition process. In some embodiments, Mg is doped into the P-type buffer layer 300, and a doping concentration of Mg ranges from 1.0×10¹⁸ atoms/cm³ to 2.0×10¹⁸ atoms/cm³. The P-type particles may be doped into the P-type buffer layer 300 via a vapor-phase epitaxy process or a molecular beam epitaxy process.

A material of the P-type stop layer 301 may be (AlₓGa₁₋ₓ)_{0.5}In_{0.5}P, and 0≤x<1. The P-type stop layer 301 may be formed through an epitaxial deposition process. In some embodiments, Mg is doped into the P-type stop layer 301, and a doping concentration of Mg ranges from 1.0×10¹⁸ atoms/cm³ to 2.0×10¹⁸ atoms/cm³. The P-type particles may be doped into the P-type stop layer 301 via a vapor-phase epitaxy process or a molecular beam epitaxy process.

In some embodiments, the P-type semiconductor structure 302, the quantum well light-emitting layer 303, and the N-type semiconductor structure 305 are formed and stacked on the P-type stop layer 301. The quantum well light-emitting layer 303 is disposed between the N-type semiconductor structure 305 and the P-type semiconductor structure 302. The P-type semiconductor structure 302 includes a P-type current spreading layer 320 and a P-type confinement layer 321, and the P-type confinement layer 321 is disposed between the quantum well light-emitting layer 303 and the P-type current spreading layer 320.

In some embodiments, the P-type buffer layer and the P-type stop layer may not be formed, and the P-type semiconductor structure, the quantum well light-emitting layer, and the N-type semiconductor structure are formed and stacked on a surface of the substrate.

In some embodiments, the method for forming the light-emitting diode epitaxial structure includes: forming the P-type semiconductor structure 302 on the P-type stop layer 301; forming the quantum well light-emitting layer 303 on the P-type semiconductor structure 302; and forming the N-type semiconductor structure 305 on the quantum well light-emitting layer 303. Cross-sectional views corresponding to the process of forming the light-emitting diode epitaxial structure can be referred to FIG. 6.

Referring to FIG. 5 and FIG. 6, the step S21 is performed to form the P-type semiconductor structure 302 on the P-type stop layer 301.

In some embodiments, the P-type semiconductor structure is formed directly on the substrate.

In some embodiments, a method for forming the P-type semiconductor structure 302 includes: forming a P-type current spreading layer 320 on the P-type stop layer 301; and forming a P-type confinement layer 321 on the P-type current spreading layer 320.

In some embodiments, the method for forming the P-type semiconductor structure 302 further includes: forming a P-type ohmic contact layer 322 on the P-type stop layer 301 before forming the P-type current spreading layer 320. In other embodiments, the P-type ohmic contact layer 322 may not be needed.

In some embodiments, the P-type ohmic contact layer 322 serves as a P-type electrode. Moreover, the P-type ohmic contact layer 322 can protect the P-type current spreading layer 320, ensuring the performance of the P-type current spreading layer 320.

A material of the P-type ohmic contact layer 322 may be GaAs, the P-type ohmic contact layer 322 may be doped with P-type particles, and a doping concentration of the P-type particles may be greater than 1.0×10¹⁹ atoms/cm³. The P-type particles may include at least one selected from a group consisting of Mg, C, and Zn. In some embodiments, the P-type particles include C particles, and the C particles can be easily doped into the P-type ohmic contact layer 322, which ensures that the P-type ohmic contact layer 322 doped with the C particles has a high electrical conductivity. The P-type ohmic contact layer 322 may be formed through an epitaxial deposition process, and the P-type particles may be doped into the P-type ohmic contact layer 322 via a vapor-phase epitaxy process or a molecular beam epitaxy process.

In some embodiments, parameters of the epitaxial deposition process for forming the P-type ohmic contact layer 322 include: a pressure ranging from 40 mbar to 60 mbar, a temperature ranging from 700° C. to 750° C., and reaction gases including an arsenic source gas, a gallium source gas, and a P-type doping source gas.

In some embodiments, after the arsenic source gas is introduced into a process chamber which is used for the epitaxial deposition process of forming the P-type ohmic contact layer 322, the gallium source gas and the P-type doping source gas are then introduced into the process chamber. In one embodiment, the arsenic source gas includes AsH₃; and the gallium source gas includes trimethyl gallium.

The P-type confinement layer 321 is used to provide electrons to the quantum well light-emitting layer 303; and the P-type current spreading layer 320 is used for current spreading in the P-side of the light-emitting diode.

A material of the P-type current spreading layer 320 has a first lattice constant, a material of the P-type confinement layer 321 has a second lattice constant, and a mismatch between the first lattice constant and second lattice constant is less than or equal to 1%.

In some embodiments, the material of the P-type confinement layer 321 is Al_{0.5}In_{0.5}P, and a lattice constant of the Al_{0.5}In_{0.5}P is 5.65 Å. The P-type confinement layer 321 is doped with P-type particles, and the P-type particles include at least one selected from a group consisting of Mg, C, and Zn. In some embodiments, the P-type particles include Mg particles. A doping concentration of the P-type particles in the P-type confinement layer 260 ranges from 0.4×10¹⁸ atoms/cm³ to 1×10¹⁸ atoms/cm³. The P-type confinement layer 321 may be formed through an epitaxial deposition process. The P-type particles may be doped into the P-type confinement layer 321 via a vapor-phase epitaxy process or a molecular beam epitaxy process.

In some embodiments, the material of the P-type current spreading layer 320 is AlᵢGa₁₋ᵢAs, and 0.7≤i<1. A lattice constant of the AlᵢGa₁₋ᵢAs is 5.65 Å. The P-type current spreading layer 320 is doped with P-type particles, and the P-type particles include at least one selected from a group consisting of Mg, C, and Zn. In an embodiment, the P-type particles include C particles. A doping concentration of the P-type particles in the P-type current spreading layer 320 may be greater than 3.0×10¹⁸ atoms/cm³. The P-type particles may be doped into the P-type current spreading layer 320 via a vapor-phase epitaxy process or a molecular beam epitaxy process.

In some embodiments, parameters of the epitaxial deposition process for forming the P-type current spreading layer 320 includes: a pressure ranging from 40 mbar to 60 mbar, a temperature ranging from 700° C. to 750° C., and reaction gases include an arsenic source gas, a gallium source gas, an aluminum source gas, and a P-type doping source gas.

In some embodiments, after the arsenic source gas is introduced into a process chamber used for the epitaxial deposition process, the gallium source gas, the aluminum source gas and the P-type doping source gas are introduced. Therefore, the composition of Al, the composition of Ga, and the doping concentration of the P-type particles in the material can be flexibly controlled by adjusting the flow rate of the gas sources. In an embodiment, the arsenic source gas includes AsH₃; the gallium source gas includes trimethyl gallium; and the aluminum source gas includes trimethyl aluminum.

In some embodiments, the material of the P-type current spreading layer is AlGaInP.

Referring to FIG. 5 and FIG. 6, the step S22 is performed to form the second waveguide layer 304 on the P-type semiconductor structure 302 and to form the quantum well light-emitting layer 303 on the second waveguide layer 304.

In some embodiments, the method for forming the light-emitting diode epitaxial structure further includes: before forming the quantum well light-emitting layer 303, forming the second waveguide layer 304 on the P-type confinement layer 321. The second waveguide layer 304 is used to protect light-emitting regions.

The second waveguide layer 304 may be formed through an epitaxial deposition process. A material of the second waveguide layer 304 may be (AlᵤGa₁₋ᵤ)_{0.5}In_{0.5}P, and 0.6≤u<1. A lattice constant of the (AlᵤGa₁₋ᵤ)_{0.5}In_{0.5}P may be 5.65 Å. The composition u of Al in the (AlᵤGa₁₋ᵤ)_{0.5}In_{0.5}P is not less than 0.6, which provides the second waveguide layer 304 with a high light transmittance and is conducive to reducing optical loss in the quantum well light-emitting layer 303. In some embodiments, the second waveguide layer 304 is not doped with N-type particles or P-type particles.

The quantum well light-emitting layer 303 may be formed through an epitaxial deposition process. In the quantum well light-emitting layer 303, light generated by the recombination of electrons and holes radiates outwardly. A material of the quantum well light-emitting layer 303 may be Al_{w}Ga_{z}In_{1-w-z}P, O<w<1, 0<z<1, and (w+z)<1. A lattice constant of the Al_{w}Ga_{z}In_{1-w-z}P may be 5.65 Å. In some embodiments, the quantum well light-emitting layer 303 is not doped with P-type particles or N-type particles.

Referring to FIG. 5 and FIG. 6, the step S23 is performed to form the first waveguide layer 307 on the quantum well light-emitting layer 303 and to form the N-type semiconductor structure 305 on the first waveguide layer 307.

A method for forming the N-type semiconductor structure 305 includes: forming an N-type confinement layer 350 on the quantum well light-emitting layer 303; forming an N-type current spreading layer 351 on the N-type confinement layer 350; and forming an N-type ohmic contact layer 352 on the N-type current spreading layer 351.

In some embodiments, the method for forming the light-emitting diode epitaxial structure further includes: forming the first waveguide layer 307 on the quantum well light-emitting layer 303 before forming the N-type semiconductor structure 305.

The first waveguide layer 307 may be formed through an epitaxial deposition process. A material of the first waveguide layer 307 may be (AlᵥGa₁₋ᵥ)_{0.5}In_{0.5}P, and 0.6≤v<1. A lattice constant of the (AlᵥGa₁₋ᵥ)_{0.5}In_{0.5}P may be 5.65 Å. The composition v of Al in the (AlᵥGa₁₋ᵥ)_{0.5}In_{0.5}P is not less than 0.6, which provides the first waveguide layer 307 with a light transmittance and is conducive to reducing optical loss in the quantum well light-emitting layer 303. In some embodiments, the first waveguide layer 307 is not doped with N-type particles or P-type particles.

In other embodiments, any one of the first waveguide layer and the second waveguide layer can be formed.

The N-type ohmic contact layer 352 serves as an N-type electrode, the N-type current spreading layer 351 is used for current spreading in the N-side of the light-emitting diode, and the N-type confinement layer 232 is used to provide electrons to the quantum well light-emitting layer 303.

A material of the N-type ohmic contact layer 352 may be GaAs. The N-type ohmic contact layer 352 may be formed through an epitaxial deposition process. The N-type ohmic contact layer 352 may be doped with N-type particles, and the N-type particles may include at least one selected from a group consisting of Si and Te. In some embodiments, the N-type particles include Si particles, and a doping concentration of the Si particles is more than 5.0×10¹⁸ atoms/cm³. The N-type particles may be doped into the N-type ohmic contact layer 352 via a vapor-phase epitaxy process or a molecular beam epitaxy process. The N-type ohmic contact layer 352 with a relatively high doping concentration of the N-type particles can readily form an ohmic contact with other electrically connected structures.

A material of the N-type current spreading layer 351 may be (Al_{y}Ga_{1-y})_{0.5}In_{0.5}P, and 0<y<1. The N-type current spreading layer 351 may be formed through an epitaxial deposition process. The N-type current spreading layer 351 may be doped with N-type particles, and the N-type particles may include at least one selected from a group consisting of Si and Te. In some embodiment, the N-type particles include Si particles, and a doping concentration of the Si particles is more than 1.0×10¹⁸ atoms/cm³ to 2.0×10¹⁸ atoms/cm³. The N-type particles may be doped into the N-type current spreading layer 351 via a vapor-phase epitaxy process or a molecular beam epitaxy process.

A material of the N-type confinement layer 350 may be Al_{0.5}In_{0.5}P. The N-type confinement layer 350 may be formed through an epitaxial deposition process. The N-type confinement layer 350 may be doped with N-type particles, and the N-type particles may include at least one selected from a group consisting of Si and Te. In some embodiment, the N-type particles include Si particles, and a doping concentration of the Si particles is more than 1.0×10¹⁸ atoms/cm³ to 2.0×10¹⁸ atoms/cm³. The N-type particles may be doped into the N-type confinement layer 350 via a vapor-phase epitaxy process or a molecular beam epitaxy process.

In some embodiments, the method for forming the light-emitting diode includes: after forming the N-type semiconductor structure 305, removing the substrate 306 until a surface of the P-type ohmic contact layer 322 is exposed. A process for removing the substrate 306 may include: a dry etching process, a wet etching process, and a chemical mechanical polishing process.

Accordingly, some embodiments of the present disclosure also provide a light-emitting diode epitaxial structure which can be formed through aforementioned method. Referring to FIG. 6, the light-emitting diode epitaxial structure formed through the aforementioned method includes: a substrate 306; a P-type semiconductor structure 302 disposed on the substrate 306; a quantum well light-emitting layer 303 disposed on the P-type semiconductor structure 302; and an N-type semiconductor structure 305 disposed on the quantum well light-emitting layer 303. The P-type semiconductor structure 302 includes a P-type current spreading layer 320 and a P-type confinement layer 321, and the P-type confinement layer 321 and the P-type current spreading layer 320 are in close contact and matched in lattice.

Following provides a detailed description in conjunction with the accompanying drawings.

In some embodiments, a material of the P-type current spreading layer 320 has a first lattice constant, a material of the P-type confinement layer 321 has a second lattice constant, and a mismatch between the first lattice constant and the second lattice constant is less than or equal to 1%.

In some embodiments, a P-type buffer layer 300 is also formed on the substrate 306, and a P-type stop layer 301 is formed on the P-type buffer layer 300. The P-type buffer layer 300 and the P-type stop layer 301 are doped with P-type particles, and the P-type particles include at least one selected from a group consisting of Mg, C, and Zn.

A material of the P-type buffer layer 300 may be GaAs. In some embodiments, the P-type buffer layer 300 is doped with Mg, and a doping concentration of Mg ranges from 1.0×10¹⁸ atoms/cm³ to 2.0×10¹⁸ atoms/cm³.

A material of the P-type stop layer 301 may be (AlₓGa₁₋ₓ)_{0.5}In_{0.5}P, and 0≤x<1. The P-type stop layer 301 may be doped with Mg, and a doping concentration of Mg may range from 1.0×10¹⁸ atoms/cm³ to 2.0×10¹⁸ atoms/cm³.

In some embodiments, the light-emitting diode epitaxial structure may not include the P-type buffer layer and the P-type stop layer.

In some embodiments, the P-type semiconductor structure 302 further includes a P-type ohmic contact layer 322 disposed on the P-type stop layer 301. The P-type current spreading layer 320 is disposed on the P-type ohmic contact layer 322. In some embodiments, the P-type semiconductor structure 302 may not include the P-type ohmic contact layer 322.

The P-type ohmic contact layer 322 serves as a P-type electrode. Moreover, the P-type ohmic contact layer 322 can protect the P-type current spreading layer 320, ensuring the performance of the P-type current spreading layer 320.

A material of the P-type ohmic contact layer 322 may be GaAs, the P-type ohmic contact layer 322 may be doped with P-type particles, and a doping concentration of the P-type particles may be greater than 1.0×10¹⁹ atoms/cm³. The P-type particles may include at least one selected from a group consisting of Mg, C, and Zn. In some embodiments, the P-type particles include C particles.

The P-type confinement layer 321 may be used to provide holes to the quantum well light-emitting layer 303; and the P-type current spreading layer 320 may be used for current spreading in the P-side of the light-emitting diode.

The material of the P-type current spreading layer 320 has a first lattice constant, the material of the P-type confinement layer 321 has a second lattice constant, and the mismatch between the first lattice constant and the second lattice constant is less than or equal to 1%.

In some embodiments, the material of the P-type confinement layer 321 is Al_{0.5}In_{0.5}P, and a lattice constant of the Al_{0.5}In_{0.5}P is 5.65 Å. The P-type confinement layer 321 may be doped with P-type particles, and the P-type particles may include at least one selected from a group consisting of Mg, C, and Zn. In some embodiments, the P-type particles include Mg particles. A doping concentration of the P-type particles in the P-type confinement layer 260 ranges from 0.4×10¹⁸ atoms/cm³ to 1×10¹⁸ atoms/cm³.

In some embodiments, the material of the P-type current spreading layer 320 is AlᵢGa₁₋ᵢAs, and 0.7≤i<1. A lattice constant of the AlᵢGa₁₋ᵢAs is 5.65 Å. The P-type current spreading layer 320 is doped with P-type particles, and the P-type particles include at least one selected from a group consisting of Mg, C, and Zn. In an embodiment, the P-type particles include C particles. A doping concentration of the P-type particles in the P-type current spreading layer 320 is greater than 3.0×10¹⁸ atoms/cm³.

In some embodiments, the material of the P-type current spreading layer is AlGaInP.

In some embodiments, a second waveguide layer 304 is formed between the quantum well light-emitting layer 303 and the P-type confinement layer. The second waveguide layer 304 is used to protect light-emitting regions.

A material of the second waveguide layer 304 may be (AlᵤGa₁₋ᵤ)_{0.5}In_{0.5}P, and 0.6≤u<1. A lattice constant of the (AlᵤGa₁₋ᵤ)_{0.5}In_{0.5}P may be 5.65 Å. The composition u of Al in the (AlᵤGa₁₋ᵤ)_{0.5}In_{0.5}P is not less than 0.6, which is conducive to improving a high light transmittance of the second waveguide layer 304. In some embodiments, the second waveguide layer 304 is not doped with N-type particles or P-type particles.

In the quantum well light-emitting layer 303, light generated by the recombination of electrons and holes radiates outwardly. A material of the quantum well light-emitting layer 303 may be Al_{w}Ga_{z}In_{1-w-z}P, 0<w<1, 0<z<1, and (w+z)<1. A lattice constant of the Al_{w}Ga_{z}In_{1-w-z}P may be 5.65 Å. In some embodiments, the quantum well light-emitting layer 303 is not doped with P-type particles or N-type particles.

In some embodiments, a first waveguide layer 307 is formed between the quantum well light-emitting layer 303 and the N-type semiconductor structure 305.

A material of the first waveguide layer 307 may be (AlᵥGa₁₋ᵥ)_{0.5}In_{0.5}P, and 0.6≤v<1. A lattice constant of the (AlᵥGa₁₋ᵥ)_{0.5}In_{0.5}P may be 5.65 Å. The composition v of Al in the (AlᵥGa₁₋ᵥ)_{0.5}In_{0.5}P is not less than 0.6, which is conducive to improving a light transmittance of the first waveguide layer 307. In some embodiments, the first waveguide layer 307 is not doped with N-type particles or P-type particles.

In some embodiments, the light-emitting diode epitaxial structure may include only one of the first waveguide layer and the second waveguide layer.

The N-type semiconductor structure 305 includes: an N-type confinement layer 350 disposed on the quantum well light-emitting layer 303; an N-type current spreading layer 351 disposed on the N-type confinement layer 350; and an N-type ohmic contact layer 352 disposed on the N-type current spreading layer 351.

The N-type ohmic contact layer 352 serves as an N-type electrode, the N-type current spreading layer 351 is used for current spreading in the N-side of the light-emitting diode, and the N-type confinement layer 350 is used to provide electrons to the quantum well light-emitting layer 303.

A material of the N-type ohmic contact layer 352 may be GaAs. The N-type ohmic contact layer 352 may be doped with N-type particles, and the N-type particles may include at least one selected from a group consisting of Si and Te. In some embodiments, the N-type particles include Si particles, and a doping concentration of the Si particles is more than 5.0×10¹⁸ atoms/cm³. The N-type ohmic contact layer 352 with a relatively high doping concentration of the N-type particles can readily form an ohmic contact with other electrically connected structures.

A material of the N-type current spreading layer 351 may be (Al_{y}Ga_{1-y})_{0.5}In_{0.5}P, and 0<y<1. The N-type current spreading layer 351 may be doped with N-type particles, and the N-type particles may include at least one selected from a group consisting of Si and Te. In some embodiment, the N-type particles include Si particles, and a doping concentration of the Si particles is more than 1.0×10¹⁸ atoms/cm³ to 2.0×10¹⁸ atoms/cm³.

A material of the N-type confinement layer 350 may be Al_{0.5}In_{0.5}P. The N-type confinement layer 350 may be doped with N-type particles, and the N-type particles may include at least one selected from a group consisting of Si and Te. In some embodiment, the N-type particles include Si particles, and a doping concentration of the Si particles is more than 1.0×10¹⁸ atoms/cm³ to 2.0×10¹⁸ atoms/cm³.

In some embodiments, the N-type particles include N-type atoms or N-type ions; and the P-type particles include P-type atoms or P-type ions.

FIG. 7 schematically illustrates a cross-sectional view of a light-emitting diode epitaxial structure according to another embodiment of the present disclosure.

Unlike the embodiments illustrated in FIG. 5 and FIG. 6, in this embodiment, neither a P-type buffer layer nor a P-type stop layer is formed on a surface of a substrate 306, and the P-type semiconductor structure 302 is directly formed on the surface of the substrate 306. A method for forming a light-emitting diode epitaxial structure includes: forming the P-type semiconductor structure 302 on the substrate 306; forming the quantum well light-emitting layer 303 on the P-type semiconductor structure 302; and forming the N-type semiconductor structure 305 on the quantum well light-emitting layer 303.

The process of forming the light-emitting diode epitaxial structure is illustrated in FIG. 5 to FIG. 6 and related description, and is not be repeated herein.

The aforementioned light-emitting diode epitaxial structures can be applied on a microdisplay panel.

The microdisplay panel described above has a very small volume, with dimensions of length and width ranging from 500 μm to 50,000 μm. An area of a light-emitting region of the microdisplay panel is very small, such as 1 mm×1 mm, 2.64 mm×2.02 mm, 3 mm×5 mm, and the like. The light-emitting region of the microdisplay panel includes a plurality of micro LED pixels arranged in an array, and a specific pixel arrangement may be one of 320×240, 640×480, 1600×1200, 1920×1080, and 2560×1440. A dimension of a single micro LED pixel ranges from 100 nm to 100 μm. In some embodiments, the dimension of the single micro LED pixel ranges from 150 nm to 15 μm. In some embodiments, the dimension of the single micro LED pixel may also be less than 10 μm.

A driver backplane is configured on a back of the micro LED pixel array and electrically connected with the micro LEDs in the micro LED pixel array. The driver backplane is capable of receiving image data and other signals from external sources and controlling the corresponding micro-LEDs to emit or not emit light. The driver backplane is either a Thin Film Transistor (TFT) board or an Integrated Circuit (IC) board.

In some embodiments, a frame buffer, a column driver circuit, and a row driver circuit are integrated in the driver backplane of the microdisplay panel, the frame buffer includes a first pixel storage area, and the micro LED pixel array includes a second pixel storage area. A complete frame of pixel grayscale data from the outside can first enter the first pixel storage area of the frame buffer, the column driver circuit can load the pixel grayscale data from the first pixel storage area of the frame buffer into the second pixel storage area of the micro LED pixel array, and the row driver circuit can scan the pixel grayscale data in the second pixel storage area and generate pulse modulation signals to achieve the display of varying grayscale levels. When driving multiple micro LED pixels in the micro LED pixel array, either a single pixel can be driven independently or a plurality of pixel units can be driven independently, and the specific driving method should not constitute a limitation of the present disclosure.

It should be noted that the application of the aforementioned light-emitting diode epitaxial structure in the manufacturing process of microdisplay panels should not constitute a limitation on the application of the present disclosure.

Although the present disclosure has been disclosed above, the present disclosure is not limited thereto. Any changes and modifications may be made by those skilled in the art without departing from the spirit and scope of the present disclosure, and the scope of the present disclosure should be determined by the appended claims.

What is claimed is:

1. A light-emitting diode epitaxial structure, comprising:
an N-type semiconductor structure;
a quantum well light-emitting layer disposed on the N-type semiconductor structure; and
a P-type semiconductor structure disposed on the quantum well light-emitting layer, wherein the P-type semiconductor structure comprises a P-type current spreading layer and a P-type confinement layer, the P-type confinement layer is disposed between the quantum well light-emitting layer and the P-type current spreading layer, and the P-type confinement layer and the P-type current spreading layer are in close contact and matched in lattice.

2. The light-emitting diode epitaxial structure according to claim 1, wherein a material of the P-type current spreading layer has a first lattice constant, a material of the P-type confinement layer has a second lattice constant, and a mismatch between the first lattice constant and the second lattice constant is less than or equal to 1%.

3. The light-emitting diode epitaxial structure according to claim 1, wherein a material of the P-type confinement layer is Al_{0.5}In_{0.5}P, a material of the P-type current spreading layer is AlᵢGa₁₋ᵢAs, and 0.7≤i<1.

4. The light-emitting diode epitaxial structure according to claim 3, wherein the P-type current spreading layer is doped with P-type particles, a doping concentration of the P-type particles in the P-type current spreading layer is greater than 3.0×10¹⁸ atoms/cm³, and the P-type particles comprise at least one selected from a group consisting of Mg, C, and Zn.

5. The light-emitting diode epitaxial structure according to claim 1, wherein the P-type semiconductor structure further comprises a P-type ohmic contact layer, and the P-type ohmic contact layer and the P-type confinement layer are respectively disposed on opposite sides of the P-type current spreading layer.

6. The light-emitting diode epitaxial structure according to claim 5, wherein a material of the P-type ohmic contact layer is GaAs, the P-type ohmic contact layer is doped with P-type particles, a doping concentration of the P-type particles is greater than 1.0×10¹⁹ atoms/cm³, and the P-type particles comprise at least one selected from a group consisting of Mg, C, and Zn.

7. The light-emitting diode epitaxial structure according to claim 1, wherein the N-type semiconductor structure comprises an N-type confinement layer, an N-type current spreading layer, and an N-type ohmic contact layer;
the N-type confinement layer is disposed between the quantum well light-emitting layer and the N-type current spreading layer; and
the N-type current spreading layer is disposed between the N-type confinement layer and the N-type ohmic contact layer.

8. The light-emitting diode epitaxial structure according to claim 7, wherein a material of the N-type confinement layer is Al_{0.5}In_{0.5}P, a material of the N-type current spreading layer is (Al_{y}Ga_{1-y})_{0.5}In_{0.5}P, and 0<y<1;
a material of the N-type ohmic contact layer is GaAs; and
the N-type confinement layer, the N-type current spreading layer, and the N-type ohmic contact layer are all doped with N-type particles, and the N-type particles comprise at least one selected from a group consisting of Si and Te.

9. The light-emitting diode epitaxial structure according to claim 1, further comprising: a first waveguide layer and/or a second waveguide layer, wherein the first waveguide layer is disposed between the quantum well light-emitting layer and the N-type semiconductor structure, and the second waveguide layer is disposed between the quantum well light-emitting layer and the P-type confinement layer.

10. The light-emitting diode epitaxial structure according to claim 9, wherein a material of the first waveguide layer comprises (AlᵥGa₁₋ᵥ)_{0.5}In_{0.5}P, and 0.6≤v<1; and a material of the second waveguide layer comprises (AlᵤGa₁₋ᵤ)_{0.5}In_{0.5}P, and 0.6≤u<1.

11. The light-emitting diode epitaxial structure according to claim 1, further comprising: a substrate;
wherein the N-type semiconductor structure is disposed between the quantum well light-emitting layer and the substrate, or the P-type semiconductor structure is disposed between the quantum well light-emitting layer and the substrate.

12. The light-emitting diode epitaxial structure according to claim 11, further comprising: a stop layer disposed on the substrate, wherein the stop layer is disposed between the substrate and the quantum well light-emitting layer.

13. The light-emitting diode epitaxial structure according to claim 12, wherein a material of the stop layer is (AlₓGa₁₋ₓ)_{0.5}In_{0.5}P, and 0≤x<1.

14. The light-emitting diode epitaxial structure according to claim 12, further comprising: a buffer layer disposed on the substrate, wherein the buffer layer is disposed between the substrate and the stop layer.

15. The light-emitting diode epitaxial structure according to claim 14, wherein a material of the buffer layer is GaAs.

16. The light-emitting diode epitaxial structure according to claim 11, wherein a material of the substrate is GaAs.

17. A method for forming a light-emitting diode epitaxial structure, comprising:
providing a substrate;
forming an N-type semiconductor structure on the substrate;
forming a quantum well light-emitting layer on the N-type semiconductor structure;
forming a P-type confinement layer on the quantum well light-emitting layer; and
forming a P-type current spreading layer on the P-type confinement layer, wherein the P-type confinement layer and the P-type current spreading layer are in close contact and matched in lattice.

18. The method according to claim 17, wherein a material of the P-type current spreading layer has a first lattice constant, a material of the P-type confinement layer has a second lattice constant, and a mismatch between the first lattice constant and the second lattice constant is less than or equal to 1%.

19. The method according to claim 17, further comprising: forming a P-type ohmic contact layer on the P-type current spreading layer.

20. The method according to claim 17, wherein forming the N-type semiconductor structure comprises: forming an N-type ohmic contact layer on the substrate; forming an N-type current spreading layer on the N-type ohmic contact layer; and forming an N-type confinement layer on the N-type current spreading layer.

21. The method according to claim 17, further comprising: forming an N-type buffer layer on the substrate before forming the N-type semiconductor structure; and forming an N-type stop layer on the N-type buffer layer.

22. The method according to claim 17, wherein a material of the P-type current spreading layer is AlᵢGa₁₋ᵢAs, 0.7≤i<1, the P-type current spreading layer is doped with P-type particles, a doping concentration of the P-type particles in the P-type current spreading layer is greater than 3.0×10¹⁸ atoms/cm³, and the P-type particles comprise at least one selected from a group consisting of Mg, C, and Zn.

23. The method according to claim 22, wherein the P-type current spreading layer is formed through an epitaxial deposition process;
parameters of the epitaxial deposition process for forming the P-type current spreading layer comprises: a pressure ranging from 40 mbar to 60 mbar, a temperature ranging from 700° C. to 750° C., and reaction gases comprising an arsenic source gas, a gallium source gas, an aluminum source gas, and a P-type doping source gas; and
after the arsenic source gas is introduced into a process chamber used for the epitaxial deposition process, the gallium source gas, the aluminum source gas and the P-type doping source gas are introduced.

24. The method according to claim 23, wherein the arsenic source gas comprises AsH₃; the gallium source gas comprises trimethyl gallium; and the aluminum source gas comprises trimethyl aluminum.

25. A method for forming a light-emitting diode epitaxial structure, comprising:
providing a substrate;
forming a P-type current spreading layer on the substrate;
forming a P-type confinement layer on the P-type current spreading layer, wherein the P-type confinement layer and the P-type current spreading layer are in close contact and matched in lattice;
forming a quantum well light-emitting layer on the P-type confinement layer; and
forming an N-type semiconductor structure on the quantum well light-emitting layer.
